(19) United States
(12) Patent Application Publication
(10) Pub. No.: US 2022/0123191 A1
(43) Pub. Date: Apr. 21, 2022

(54) LED MODULE AND DISPLAY DEVICE HAVING LED MODULE

(71) Applicant: Japan Display Inc., Tokyo (JP)

(72) Inventors: Kazuyuki YAMADA, Tokyo (JP); Keisuke ASADA, Tokyo (JP); Daiki ISONO, Tokyo (JP)

(73) Assignee: Japan Display Inc., Tokyo (JP)

(21) Appl. No.: 17/563,084

(22) Filed: Dec. 28, 2021

Related U.S. Application Data
(63) Continuation of application No. PCT/JP2020/020728, filed on May 26, 2020.

(30) Foreign Application Priority Data
Jul. 10, 2019 (JP) 2019-128742

(51) Int. Cl. H01L 33/62; H01L 25/075

(52) U.S. Cl. CPC H01L 33/62; H01L 25/0753

(57) ABSTRACT

An LED module includes a first electrode on an insulating surface, a second electrode adjacent to the first electrode, at least one groove arranged between the first electrode and the second electrode on the insulating surface, and an LED chip disposed over the first electrode and the second electrode. The LED chip is connected to the first electrode and the second electrode through conductive members.

### CROSS-REFERENCE TO RELATED APPLICATIONS

This application is a Continuation of International Patent Application No. PCT/JP2020/020728, filed on May 26, 2020, which claims priority to Japanese Patent Application No. 2019-128742, filed on Jul. 10, 2019, the disclosures of each are incorporated herein by reference for all purposes as if fully set forth herein.

### FIELD

An embodiment of the present invention relates to a structure of an LED module in which light-emitting diodes (LEDs) are bare-chip mounted. An embodiment of the present invention relates to a structure of a display device in which pixels are configured by light emitting diodes.

### BACKGROUND

A micro LED display is a display in which a microscopic light emitting diode called a micro LED is mounted on pixels arranged in a matrix. The micro LED display is common to organic EL displays using organic electroluminescent devices in that pixels are self-emitting. However, the organic EL display directly forms the organic electroluminescent device on a substrate called a backplane on which a thin film transistor (TFT) is arranged. In contrast, the micro LED display differs in that the micro LED chips are fabricated on a sapphire substrate, and then individualized and mounted to a substrate called the backplane.

The micro LED display is mounted on the substrate by so-called flip-chip bonding. The micro LED is mounted on the substrate using a flowable conductive paste or solder paste before curing. In this case, it is necessary to precisely control the feed position and feed amount of the conductive paste or solder paste. However, since the chip size of the micro LED is small, it is difficult to control the supply amount and the supply position, and when the supply amount of the conductive paste or the solder paste is too small, conduction failure occurs, and when the supply amount of the conductive paste or the solder paste is too large, short-circuit defect occurs.

### SUMMARY

An LED module in an embodiment according to the present invention includes a first electrode on an insulating surface, a second electrode adjacent to the first electrode, at least one groove arranged between the first electrode and the second electrode on the insulating surface, and an LED chip disposed over the first electrode and the second electrode. The LED chip is connected to the first electrode and the second electrode through conductive members.

A display device in an embodiment according to the present invention includes a first electrode arranged on an insulating surface on which a pixel is arranged, a second electrode adjacent to the first electrode, at least one groove arranged between the first electrode and the second electrode on the insulating surface, and an LED chip connected to the first electrode and the second electrode. The LED chip is connected to the first electrode and the second electrode through conductive members, and the at least one groove overlaps the LED chip.

### BRIEF DESCRIPTION OF DRAWINGS

FIG. 1A shows a plan view of an LED module according to an embodiment of the present invention;

FIG. 1B shows a cross-sectional view of an LED module according to an embodiment of the present invention;

FIG. 2 shows a perspective view illustrating the structure of the LED chip;

FIG. 3A shows a structure of an LED module according to an embodiment present invention in which conductive members are dropped onto electrodes disposed on a protrusion;

FIG. 3B shows a structure of an LED module according to an embodiment of the present invention in which an LED chip is mounted on electrodes dropped with conductive members;

FIG. 4A shows a plan view of an LED module according to an embodiment of the present invention;

FIG. 4B shows a cross-sectional view of an LED module according to an embodiment of the present invention;

FIG. 5A shows a plan view of an LED module according to an embodiment of the present invention;

FIG. 5B shows a cross-sectional view of an LED module according to an embodiment of the present invention;

FIG. 6A shows a cross-sectional view of an LED module according to an embodiment of the present invention;

FIG. 6B shows a plan view of an LED module according to an embodiment of the present invention;

FIG. 7 shows an embodiment of an LED module according to an embodiment of the present invention;

FIG. 8 shows a configuration of a display device according to an embodiment of the present invention;

FIG. 9 shows a cross-sectional view of a pixel in a display device according to an embodiment of the present invention;

FIG. 10 shows a cross-sectional view of a pixel in a display device according to an embodiment of the present invention; and

FIG. 11 shows a cross-sectional view of a pixel in a display device according to an embodiment of the present invention.

### DESCRIPTION OF EMBODIMENTS

Hereinafter, embodiments of the present invention will be described with reference to the drawings and the like. The present invention may be carried out in various forms without departing from the gist of the invention thereof, and is not to be construed as being limited to any of the following embodiments. Although the drawings may schematically represent the width, thickness, shape, and the like of each part in comparison with the actual embodiment in order to clarify the description, they are merely examples and do not limit the interpretation of the present invention. In the present specification and each of the figures, elements similar to those described previously with respect to the figures already mentioned are designated by the same reference numerals (or numbers followed by a, b, etc.), and a detailed description thereof may be omitted as appropriate. Furthermore, the characters “first” and “second” appended to each element are convenient signs used to distinguish each element, and have no further meaning unless specifically described.

As used herein, where a member or region is “on” (or “below”) another member or region, this includes cases where it is not only directly on (or just under) the other member or region but also above (or below) the other member or region, unless otherwise specified. That is, it includes the case where another component is included in between above (or below) other members or regions. In the following description, unless otherwise specified, it is assumed that the LED chips are “on” or “above” the substrate when the substrate is used as a reference and that the substrate is “under” or “below” the LED chips when the LED chips are used as a reference.

In the present invention, a micro LED refers to a chip having a chip size of not less than a few micrometers and not more than 100 micrometers, and a mini LED refers to a chip having a chip size of not less than 100 micrometers. In an embodiment of the present invention, LEDs of any size can be used, and can be used according to the pixel size of the LED module and display device.

### First Embodiment

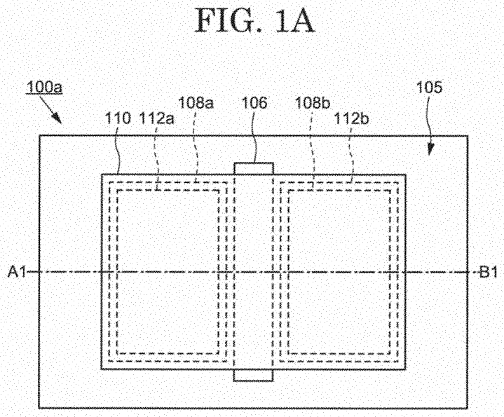

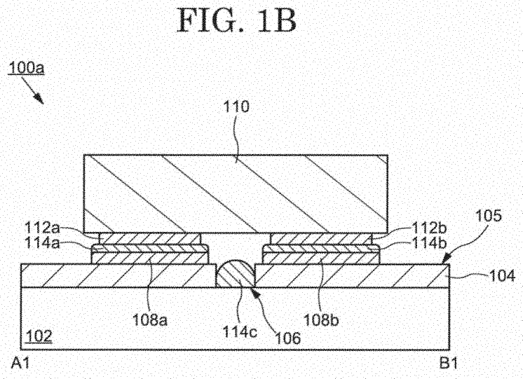

FIG. 1A and FIG. 1B show a structure of an LED module 100a according to an embodiment of the present invention. FIG. 1A shows a plan view of the LED module 100a and FIG. 1B shows a schematic cross-sectional view corresponding to the line A1-B1.

The LED module 100a has a structure in which the LED chip 110 is mounted on the first electrode 108a and the second electrode 108b is arranged on the insulating surface 105. Although not shown in FIG. 1A and FIG. 1B, wirings may be formed on a substrate 102 that are connected to the LED chip 110, or circuit that controls the emission of the LED chip 110 may be formed by thin film transistors.

The insulating surface 105 is formed by the substrate 102, which has insulating properties. Alternatively, the insulating surface 105 may be formed by a first insulating layer 104 disposed on the substrate 102. The substrate 102 is exemplified by a glass substrate or a flexible resin substrate, and the first insulating layer 104 is exemplified by a resin material such as polyimide, acrylic, or an inorganic insulating film formed of silicon oxide or the like.

The insulating surface 105 has a substantially flat surface, including an area within which a groove 106 is provided. The groove 106 is defined as an area that is lower than the surface in contact with the first electrode 108a and the second electrode 108b at the insulating surface 105. In other words, the groove 106 is a concave region relative to the insulating surface 105, and the bottom surface of the groove is located lower than the insulating surface 105. The groove 106 is formed by removing a predetermined depth from the surface of the insulating surface 105. For example, when the insulating surface 105 is formed by the substrate 102, the groove 106 is formed by removing the surface of the substrate 102 over a predetermined width and depth. Also, when the insulating surface 105 is formed by the first insulating layer 104, the groove 106 is formed by removing the surface of the first insulating layer 104 over a predetermined width and depth. At least one groove 106 is provided on the insulating surface 105.

FIG. 1B shows one aspect of the groove 106 in which the top surface of the substrate 102 is exposed by removing the first insulating layer 104 at a predetermined width and a predetermined depth. The groove 106 may be formed by removing a part of the first insulating layer 104 as shown in the figure, or may be formed by removing a part of the first insulating layer 104 although this is not shown in the figure. The groove 106 may also be formed by removing all of the corresponding regions of the first insulating layer 104 and removing a portion of the corresponding regions of the substrate 102.

The cross-sectional shape of the groove 106 may be rectangular, a truncated cone, a cone, semicircular, or semi-elliptical. The groove 106 may also have a shape as one contiguous groove or may have a shape as a dotted-line discontinuous groove. When the LED chip 110 is mounted on the first electrode 108a and the second electrode 108b by attaching conductive members, the groove 106 preferably has a size (volume of space defined by width and depth) such that the first electrode 108a and the second electrode 108b are not conducted by the conductive member 114c flowing out since the flowing conductive member 114c flows into the groove 106. That is, it is preferable that the depth of the groove 106 has a size that separates the conductive member 114c flowing into the groove 106 from the conductive members on the first electrode 108a and the second electrode 108b when the conductive members on the first electrode 108a and the second electrode 108b flow out. In order to achieve such a state, the groove 106 preferably has a depth of at least 1 μm to 20 μm, preferably 5 μm to 10 μm, for example.

The first electrode 108a and the second electrode 108b are arranged apart at the insulating surface 105. For example, the first electrode 108a and second electrode 108b are arranged so that they have the same or narrower spacing than the spacing of the pair of electrodes on the LED chip 110. The groove 106 is arranged adjacent the first electrode 108a and the second electrode 108b. For example, the groove 106 is preferably arranged between the first electrode 108a and the second electrode 108b.

The first electrode 108a and the second electrode 108b are arranged on the insulating surface 105 and have substantially the same height. On the other hand, the first electrode 108a and the second electrode 108b are arranged at positions higher than the bottom of the groove 106 when the bottom of the groove 106 is taken as a base. It may also be considered that a step portion formed by the groove 106 is interposed between the first electrode 108a and the second electrode 108b.

Although the materials for forming the first electrode 108a and the second electrode 108b are not limited, a conductive material having fluidity during application or dropping and a material having good wetting properties are selected. The first electrode 108a and the second electrode 108b are formed of a metallic material such as, for example, gold (Au), copper (Cu), silver (Ag), tin (Sn), aluminum (Al), titanium (Ti), molybdenum (Mo), tungsten (W), or alloys thereof. It may also be formed of a conductive oxide material such as indium tin oxide (ITO).

The LED chip 110 is a two-terminal device and has a first chip electrode 112a and a second chip electrode 112b for so-called flip-chip mounting. For example, the LED chip 110 has the first chip electrode 112a and the second chip electrode 112b on a side facing the first electrode 108a and the second electrode 108b. The first chip electrode 112a and the second chip electrode 112b are electrodes for emitting light from the LED chip 110, one of which is also called an n-side electrode and the other a p-side electrode. Preferably, the first chip electrode 112a and the second chip electrode 112b are formed using a metal and have a metal surface such as gold (Au) or silver (Ag).

The LED chip 110 is connected to the first electrode 108a and the second electrode 108b by a first conductive member 114a and a second conductive member 114b. The first conductive member 114a is disposed between the first chip electrode 112a and the first electrode 108a, and the second conductive member 114b is disposed between the second chip electrode 112b and the second electrode 108b. It is required that the first conductive member 114a and the second conductive member 114b be disposed in a separated state so that the first electrode 108a and the second electrode 108b are not short-circuited (in other words, so that the first chip electrode 112a and the second chip electrode 112b are not short-circuited).

A conductive paste is used for the first conductive member 114a and the second conductive member 114b. A silver paste, a carbon paste, or a paste having silver and carbon mixed therewith is used as the conductive paste. A solder paste may also be used as the first conductive member 114a and the second conductive member 114b. The conductive paste has fluidity, and is hardened by firing or simply drying after dropping onto an object. The conductive paste must be dropped accurately onto each of the first electrode 108a and the second electrode 108b. When too much conductive paste is dropped, the paste will spread and cause short circuiting between the electrodes. On the other hand, when too little conductive paste is dropped, the electrical continuity is defective, and the force (adhesive force) that fixes the LED chip 110 decreases, causing the LED chip to peel off.

After the conductive paste or solder paste is deposited on the first electrode 108a and the second electrode 108b, the conductive paste is pressed and spreads laterally when the LED chip 110 is mounted on the first electrode 108a and the second electrode 108b. In this case, when the amount of conductive paste or solder paste deposited is too large, the spread of the conductive paste or solder paste may increase, causing the first chip electrode 112a and the second chip electrode 112b to short circuit. Accordingly, precise control of the amount of supply of the conductive paste is required. However, since the size LED chip 110 is small, it is very difficult to control the supply of conductive paste or solder paste, and precise control can also reduce the productivity of the LED module 100a.

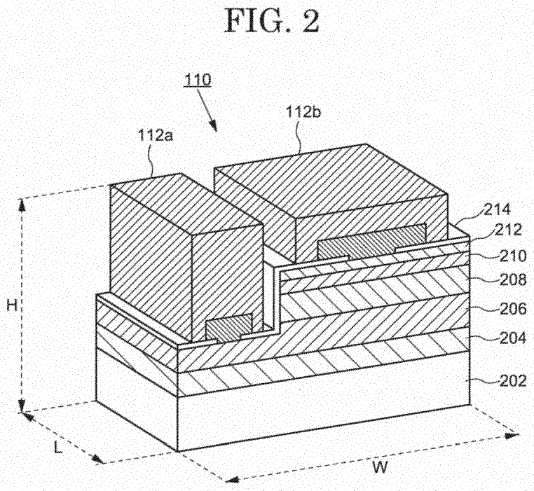

An example of the structure of the LED chip 110 is shown in FIG. 2. The LED 110 chip has a structure comprising a buffer layer 204 formed of gallium nitride or the like on a substrate 202 formed of a semiconductor wafer such as GaAs or an insulating material such as sapphire, an n-type layer 206 formed of a gallium nitride-based compound semiconductor, an active layer 208 in which a quantum well structure is formed of a gallium nitride-based compound semiconductor, a p-type layer 210 formed of a gallium nitride-based compound semiconductor, a passivation layer 214, a first chip electrode 112a, and a second chip electrode 112b. The size of the LED chip 110 is referred to as a so-called micro LED having a length L of 10 μm to 20 μm, a width W of 20 μm to 40 μm, and a height H of about 150 μm. Therefore, the distance between the first chip electrode 112a and the second chip electrode 112b is 10 μm or less. Note that the size of the LED chip 110 is not limited to the micro LED as described above, and may be of a size called a so-called mini LED.

For such microstructures, the LED module 100a has a structure that prevents short circuits between the electrodes by arranging a groove 106 adjacent the first and second electrodes 108a and 108b that contact the LED chip 110. That is, the groove 106 is arranged between the two electrodes, instead of the first electrode 108a and the second electrode 108b being arranged on the flat insulating surface 105.

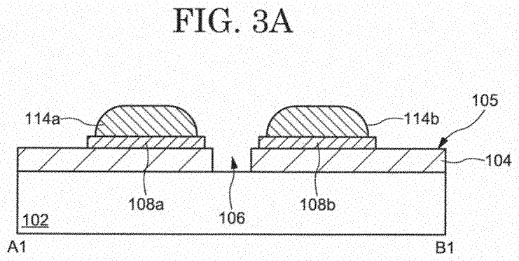

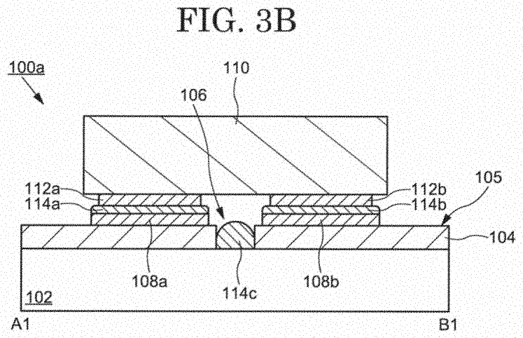

FIG. 3A shows the first conductive member 114a and the second conductive member 114b are deposited on the first electrode 108a and the second electrode 108b. The first conductive member 114a and the second conductive member 114b have fluidity and are deposited on the first electrode 108a and the second electrode 108b with a predetermined thickness.

When the LED chip 110 is placed on the first electrode 108a and the second electrode 108b in this state, as shown in FIG. 3B, the first conductive member 114a and the second conductive member 114b extend laterally by the amount of the thickness reduced by pressing of the LED chip 110 and flow out to the outside of the first electrode 108a and the second electrode 108b. Under this situation, the conductive member 114c flows into a groove 106 adjacent the first electrode 108a and the second electrode 108b. The conductive member 114c flowed into the groove 106 is separated from the first conductive member 114a on the first electrode 108a and the second conductive member 114b on the second electrode 108b. In other words, the conductive member 114c flowed into the groove 106 is separated from the first conductive member 114a on the first electrode 108a and the second conductive member 114b on the second electrode 108b by a step formed by the groove 106. As a result, the first conductive member 114a and the second conductive member 114b are prevented from conducting through the flowed conductive member 114c, thereby preventing a short circuit between the electrodes of the LED chip 110.

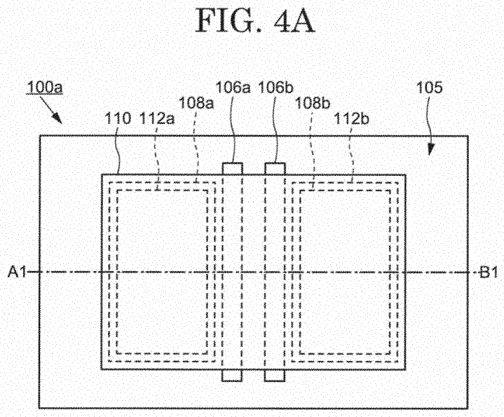

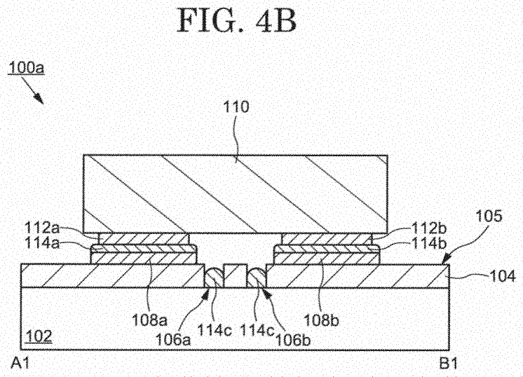

A plurality of grooves may be provided. For example, a first groove 106a and a second groove 106b may be interposed between the first electrode 108a and the second electrode 108b, as shown in a plan view of FIG. 4A and in a cross-sectional view of FIG. 4B. Preferably, the first groove 106a and the second groove 106b are arranged to separate the first electrode 108a and the second electrode 108b. The plurality of grooves ensures that the conductive members 114c flowing out from the first electrode 108a and second electrode 108b can be collected. Thus, it is possible to prevent a short circuit between the electrodes of the LED chip 110. The first groove 106a and the second groove 106b need not have the same width and depth, and may have different shapes and sizes.

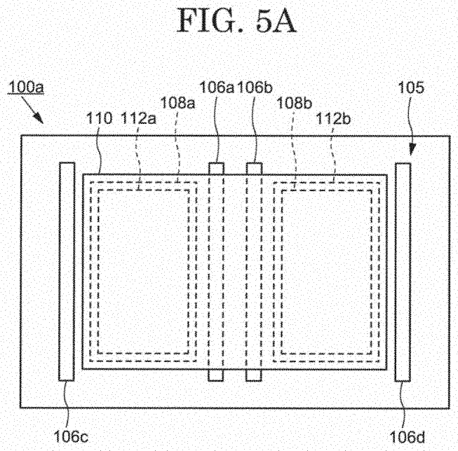

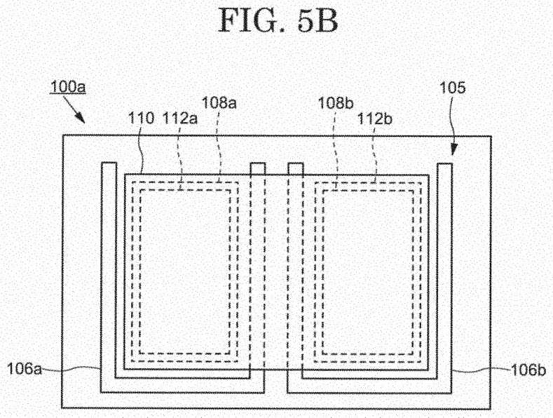

The groove 106 may also be arranged in other areas as well as between the first electrode 108a and the second electrode 108b. For example, as shown in the plan view of FIG. 5A, the third groove 106c and the fourth groove 106d may be arranged in addition to the first groove 106a and the second groove 106b between the first electrode 108a and the second electrode 108b. The third groove 106c and the first groove 106a may be arranged to interpose the first electrode 108a, and the fourth groove 106d and the second groove 106b may be arranged to interpose the second electrode 108b.

As shown in a plan view of FIG. 5B, the first groove 106a and the second groove 106b may have a U-shape or a C-shape in the plan view and may be arranged around the first electrode 108a and the second electrode 108b. Thus, the groove 106 may be arranged to sandwich or enclose the first electrode 108a and the second electrode 108b to reliably capture the conductive members flowing out of the first electrode 108a and the second electrode 108b. According to the present configuration, the conductive member flowing out of the region between the first electrode 108a and the second electrode 108b can be collected to prevent short circuits with adjacent LED chips. Such a configuration can prevent short circuiting of the LED chip 110.

According to the present embodiment, it is possible to prevent short-circuiting between the electrodes due to outflow of the conductive member 114 by arranging the groove 106 on the surface of the LED chip 110 so as to be interposed between or adjacent to the first electrode 108a and the second electrode 108b. Since the groove 106 is arranged, the occurrence of short-circuit defects in the LED module 100a can be prevented, and the yield in manufacturing can be improved. Also, even when the conductive member 114 (the first conductive member 114a, the second conductive member 114b) is migrated after the fabrication of the LED module 100a, the step is formed by the groove 106 to prevent the generation of short circuit defects in the LED chip 110.

### Second Embodiment

This embodiment shows an aspect in which the insulating surfaces are different from the LED module shown in the first embodiment. In the following description, the difference from the first embodiment will be described.

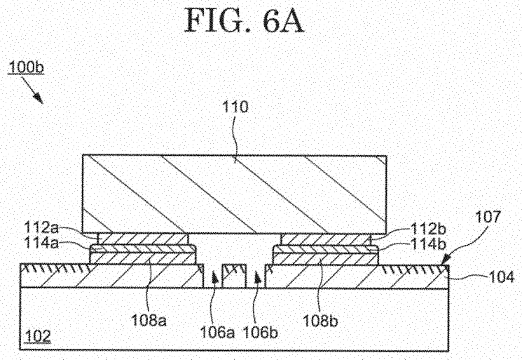

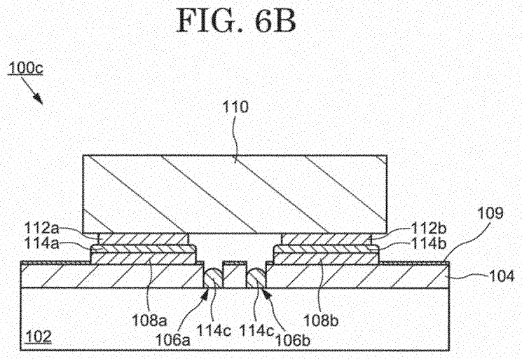

FIG. 6A shows an LED module 100b according to this embodiment. In this embodiment, the LED module 100b comprises an insulating surface 107 having liquid-repellency. The insulating surfaces 107 having liquid-repellency are formed, for example, by reforming the surface of the first insulating layer 104 to have liquid-repellency. For example, the surface of the first insulating layer 104 formed of a resinous material such as polyimide, acrylic, epoxy, or inorganic insulating material such as silicon oxide can be plasma treated with fluorine-based gas to form a liquid-repellent surface.

The groove 106 (first groove 106a and second groove 106b) may be formed by laser processing or the like after reforming the first insulating layer 104 to have liquid-repellency. Accordingly, the surface of the first insulating layer 104 becomes liquid-repellent, and the groove 106 (first groove 106a and second groove 106b) can be relatively hydrophilic. For example, when the first insulating layer 104 is formed of silicon oxide, the silicon oxide film is hydrophilic, so that the groove 106 (first groove 106a, second groove 106b) can be made hydrophilic and the reformed surface can be made liquid-repellent.

FIG. 6B shows an LED module 100c in which a liquid-repellent layer 109 is disposed on the surface of the first insulating layer 104. The liquid-repellent layer 109 is formed of a fluoropolymer material. For example, a tetrafluoroethylene-based resin material such as PTFE (polytetrafluoroethylene), PFA (perfluoro alkoxy alkane) or FEP (perfluoro-ethylene propene copolymer) can be used as the fluoropolymer.

The liquid-repellent layer 109 is formed on the surface of the first insulating layer 104. The groove 106 (first groove 106a and second groove 106b) may be formed by laser processing or the like after the liquid-repellent layer 109 is formed on the first insulating layer 104. Thus, the groove 106 (first groove 106a and second groove 106b) can be formed while leaving the liquid-repellent layer 109 on the surface of the first insulating layer 104. Accordingly, a portion of the groove 106 (first groove 106a and second groove 106b) can be relatively hydrophilic with respect to the surface of the liquid-repellent layer 109. For example, when the first insulating layer 104 is formed of silicon oxide, since the silicon oxide film is hydrophilic, the groove 106 (first groove 106a, second groove 106b) can be made hydrophilic and the surface of the liquid-repellent layer 109 can be made liquid-repellent.

According to the present embodiment, the insulating surface other than the groove is made liquid-repellent so that the conductive member 114c flowing out of the surface of the first electrode 108a and the second electrode 108b does not remain on the insulating surface and flows into the groove 106. Therefore, it is possible to prevent the short circuit defect of the LED module 100a from occurring and improve the manufacturing yield. Also, even when the conductive member 114 (the first conductive member 114a, the second conductive member 114b) is migrated after the fabrication of the LED module 100a, the step is formed by the groove 106 to prevent the generation of short circuit defects in the LED chip 110.

### Third Embodiment

This embodiment shows an embodiment of an LED module in which LED chips are arranged in multiple arrays on a substrate and connected by wiring.

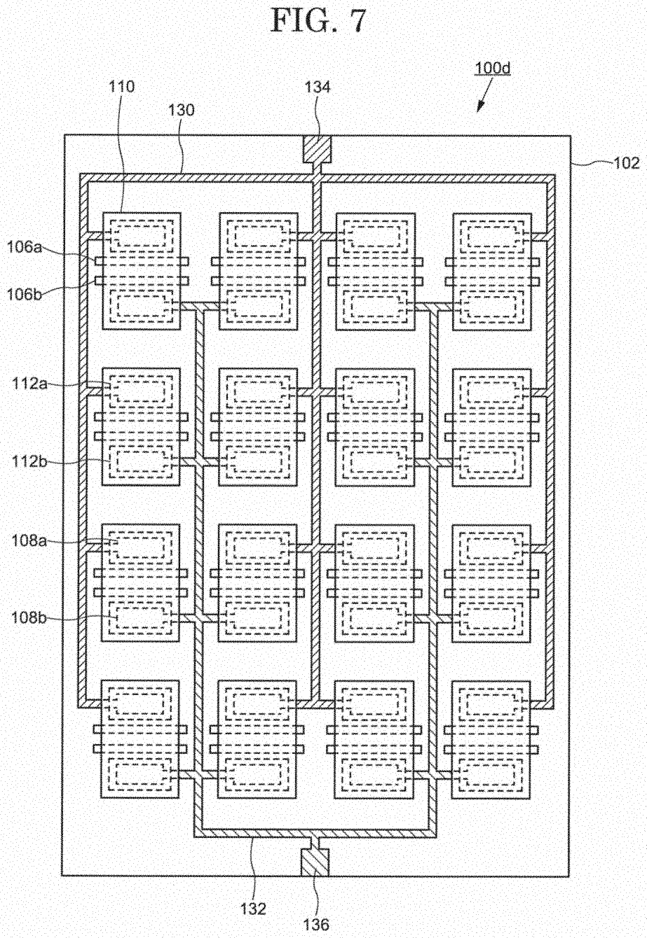

FIG. 7 shows an LED module 100d according to this embodiment. The LED module 100d has a configuration in which the LED chips 110 are mounted on the substrate 102. The substrate 102 has an insulating surface and is arranged with the first electrode 108a and the second electrode 108b in alignment with the position at which the LED chips 110 are mounted. The groove 106 (first groove 106a and second groove 106b) is formed between the first electrode 108a and the second electrode 108b. The LED chips 110 each have the first chip electrode 112a and the second chip electrode 112b and is connected to the first electrode 108a and the second electrode 108b via the conductive member, although not shown in the diagram. The first wiring 130 is also connected to the first electrode 108a and the second wiring 132 is connected to the second electrode 108b. The first wiring 130 is connected to the first terminal 134 and the second wiring 132 is connected to the second terminal 136.

When the first electrode 108a of the LED module 100d is the n-type electrode and the second electrode 108b is the p-type electrode, the LED chip 110 emits light when a forward bias voltage is applied in which a potential of the second terminal 136 is higher than that of the first terminal 134. The LED module 100d can be used as a surface light source. The LED chip 110 is not limited to the number shown and may be mounted at a higher density on the substrate 102.

The first electrode 108a and second electrode 108b, and the groove 106 arranged on the substrate 102 may be configured in any of the configurations shown in the first and second embodiments. The LED module 100d shown in FIG. 7 is a circuit in which a plurality of LED chips 110 are connected in parallel. In this circuit, while each LED chip can emit light uniformly, when one LED chip is short-circuited, the current is concentrated in the short-circuited part, and the current does not flow to the other LED chips, resulting in a lighting failure. However, since the groove 106 is arranged in the portion where the LED chip 110 is mounted in the present embodiment, the occurrence of short-circuit defects can be effectively prevented. As a result, the reliability of the LED module 110d can be enhanced.

### Fourth Embodiment

This embodiment shows a display device having the LED module configuration as illustrated in the first and second embodiments.

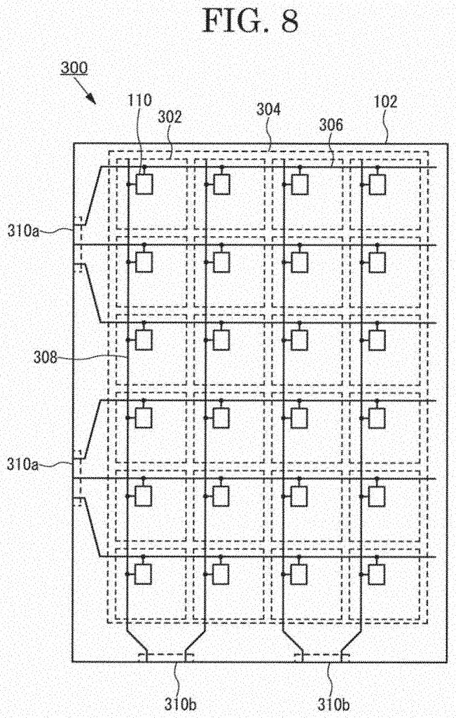

FIG. 8 shows the configuration of a display device 300 according to the present embodiment. The display device 300 includes a display part 304 on the substrate 102 with pixels 302 arranged in a matrix. Each pixel 302 is mounted with the LED chip 110. Each pixel of the display part 304 may be mounted with the LED chip 110 which emits light of a different color. For example, a red light emitting LED chip, a green light emitting LED chip, and a blue light emitting LED chip may be mounted as appropriate. Alternatively, the LED chips emitting white light may be mounted on each pixel as a color filter type display device, and the LED chips emitting blue or ultraviolet light may be mounted on each pixel as a quantum dot display device. A scanning signal line 306 for inputting a scanning signal to the pixel 302 and a data signal line 308 for inputting a video signal are arranged outside the display part 304. The scanning signal line 306 and the data signal line 308 are arranged to intersect. The peripheral part of the substrate 102 is arranged with an input terminal 310a of the scanning signal line 306 and an input terminal 310b of the data signal line 308. Although not shown in FIG. 8, a driver IC for driving the pixel 302 may be mounted on the substrate 102.

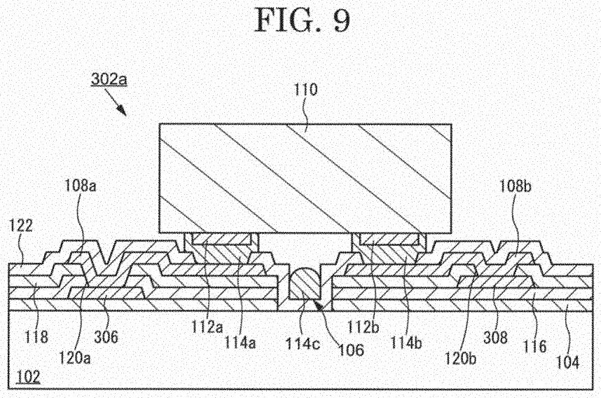

FIG. 9 shows an example of a cross-sectional structure of the pixel 302a shown in FIG. 8. The pixel 302a has a structure in which the first insulating layer 104, a second insulating layer 116, and a third insulating layer 118 are laminated from the substrate 102 side, and the first electrode 108a and the second electrode 108b are arranged on an insulating surface formed by the third insulating layer 118. The scanning signal line 306 is arranged between the first insulating layer 104 and the second insulating layer 116, and the data signal line 308 is arranged between the second insulating layer 116 and the third insulating layer 118. The second insulating layer 116 is disposed between the scanning signal line 306 and the data signal line 308 so that the two signal lines cross each other in the display part 304.

The first electrode 108a is connected to the scanning signal line 306 via a contact hole 120a passing through the third insulating layer 118 and the second insulating layer 116. The second electrode 108b is arranged to overlap the contact hole 120b passing through the third insulating layer 118 and is connected to the data signal line 308. A passivation layer 122 may be further disposed on the upper side of the first electrode 108a and the second electrode 108b. The passivation layer 122 is arranged with an opening at a region where the first electrode 108a and the second electrode 108b are connected to the LED chip 110.

The LED chip 110 is arranged on the first electrode 108a and the second electrode 108b. The first chip electrode 112a is connected to the first electrode 108a via the first conductive member 114a, and the second chip electrode 112b is connected to the second electrode 108b via the second conductive member 114b. The pixel 302a has the groove 106 between the first electrode 108a and the second electrode 108b. The groove 106 is formed by partially removing an insulating layer formed on the substrate 102. When several insulating layers are stacked on the substrate 102, the groove 106 may be formed by removing all or some of the stacked insulating layers. The groove 106 is formed by removing the third insulating layer 118, the second insulating layer 116, and the first insulating layer 104. The passivation layer 122 may be disposed on the groove 106.

The pixel 302a has a structure in which the groove 106 is formed between the first electrode 108a and the second electrode 108b to prevent a short circuit between the electrodes of the LED chip 110 even when the first conductive member 114a and the second conductive member 114b flow laterally. In other words, the pixel 302a has the groove 106 separating the flat surface between the first electrode 108a and the second electrode 108b, thereby inhibiting the flow of the flowing conductive member 114c on the plane and preventing the short circuit of the LED chip 110. With this structure, even if the amount of the conductive member supplied onto the first electrode 108a and the second electrode 108b becomes excessive in the LED chip mounting process, a short circuit between the LED chips 110 can be prevented, and the productivity and the yield of the display device 300 can be improved.

Although FIG. 8 shows an example of a passive matrix type display device, the present embodiment is not limited thereto, and may also be applied to an active matrix type display device in which the emission of individual pixels is controlled by pixel circuitry by a transistor.

### Fifth Embodiment

This embodiment shows a different embodiment of the groove with respect to the structure of the pixel illustrated in the fourth embodiment. The following description describes a part that differs from the fourth embodiment.

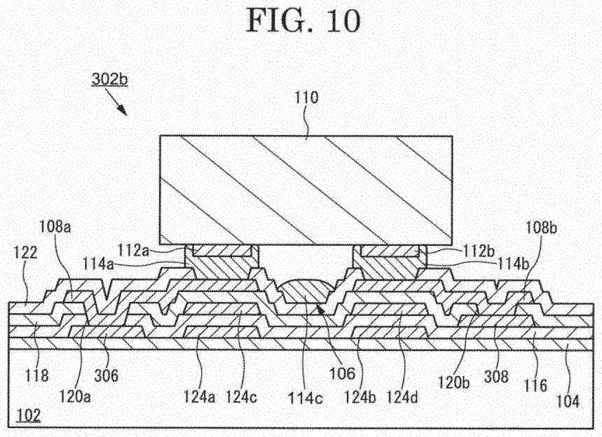

FIG. 10 is a cross-sectional view showing another embodiment of a pixel. In this embodiment, the groove 106 is formed by steps generated by the insulating layer being disposed along the surface of the structure formed in a predetermined pattern. Specifically, as shown in FIG. 10, the pixel 302b has a first structure 124a and a second structure 124b between the first insulating layer 104 and the second insulating layer 116. The first structure 124a and the second structure 124b have two distinct structures in a cross-sectional view. The first structure 124a is arranged in an area overlapping the first electrode 108a, and the second structure 124b is arranged in an area overlapping the second electrode 108b. The second insulating layer 116 is disposed along the sides and top surfaces of the first structure 124a and the second structure 124b. The upper surface of the second insulating layer 116 has a height difference between a region in contact with the first structure 124a and the second structure 124b and a region in contact with the first insulating layer 104. The second insulating layer 116 has a recessed region between the first structure 124a and the second structure 124b with respect to the region of the upper surface of the first structure 124a and the second structure 124b, so that the groove 106 is substantially formed.

It is possible to increase the depth of the groove 106 by increasing the thickness of the first structure 124a and the second structure 124b. Also, as shown in FIG. 10, a third structure 124c overlapping the first structure 124a can be arranged on the second insulating layer 116, and a fourth structure 124d overlapping the second structure 124b can be arranged to increase the depth of the groove 106.

Since the structure 124 (first structure 124a, second structure 124b, third structure 124c, fourth structure 124d) is covered with the insulating layer, the material for forming the structure is not limited. The structure 124 may be formed of a metal, a semiconductor material, or an insulating material. For example, the first structure 124a and the second structure 124b are arranged on the same layer as the scanning signal line 306 and may be formed by a metal film forming the wirings. For example, the first structure 124a and the second structure 124b may be formed by an aluminum (Al) film or a laminate with a titanium (Ti) film laminated on the underlayer and upper layer side of the aluminum (Al) film. Since the third structure 124c and the fourth structure 124d are arranged on the same layer as the data signal line 308, they can also be formed by metal films (or laminates of metal films).

As shown in the present embodiment, the groove 106 can be formed not only by partially removing the insulating layer but also by providing a pair of structures embedded in the insulating layer. The groove 106 in this embodiment can also have the same effect as in the fourth embodiment. That is, even when the first conductive member 114a and the second conductive member 114b flow laterally, the short circuit between the electrodes of the LED chip 110 can be prevented by the flowing the conductive member 114c since the groove 106 is formed between the first electrode 108a and the second electrode 108b by the structure 124 (first structure 124a, second structure 124b, third structure 124c, fourth structure 124d) and the insulating layer (second insulating layer 116, third insulating layer 118). Since the groove 106 is formed, the flow of the conductive member on the plane is inhibited and the short circuit of the LED chip 110 can be prevented, even if the supply amount of the conductive member on the first electrode 108a and the second electrode 108b becomes excessive, the short circuit between the LED chips 110 can be prevented, and the productivity of the display device 300 can be improved and the yield can be improved.

In addition, the groove formed by the structure shown in the present embodiment can be combined with the groove formed by removing a portion of the insulating layer shown in the first embodiment. Alternatively, the surface of the insulating layer can be suitably combined with a configuration in which the surface of the insulating layer is a liquid-repellent surface, as shown in the second embodiment.

### Sixth Embodiment

This embodiment shows an embodiment in which a sealing layer and a cover glass are further arranged in the pixel structure shown in the fourth embodiment. The following description describes a part that differs from the fourth embodiment.

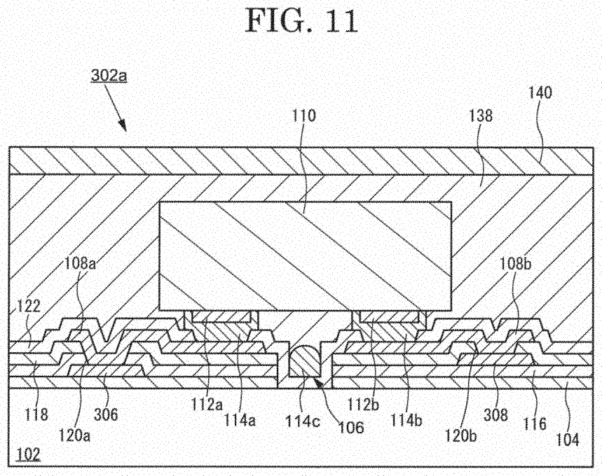

FIG. 11 shows a cross-sectional view of another embodiment of a pixel 302a. The structure of the pixel 302a shown in FIG. 11 includes a sealing layer 138 covering the LED chip 110 and a cover glass 140 disposed on the sealing layer 138. The sealing layer 138 has a function as a protective film for the LED chip 110 and as a planarization film for providing the flatness of the cover glass 140. In the structure of the pixel 302a shown in FIG. 11, in addition to preventing the short circuit between the first electrode 108a and the second electrode 108b by the groove 106, the gap between the LED chip 110 and the insulating surface 105 including the passivation layer 122 can be increased, so that the resin forming the sealing layer 138 can easily flow directly below the LED chip 110.

As shown in FIG. 11, the sealing layer 138 is also filled between the LED chip 110 and the insulating surface 105 and is in contact with the flowing conductive member 114c, particularly in the concave groove 106. When the groove 106 is not formed, the gap between the LED chip 110 and the insulating surface 105 is relatively small, so that when the sealing layer 138 is provided, the resin forming the sealing layer 138 does not flow into the small gap, which may leave a bubble between the LED chip 110 directly beneath the insulating surface 105 after laminating the cover glass 140. When the bubbles remain, light from the LED chip 110 to the substrate 102 may be reflected by the bubbles to inhibit emission characteristics, or the bubbles themselves may move within the sealing layer 138 to degrade the display characteristics. The groove 106 formed for short-circuit prevention can expand the gap between the lower side of the LED chip 110 and the insulating surface 105, and the resin can easily flow into the lower part of the LED chip 110 when the sealing layer 138 is formed, and the generation of bubbles in the lower part of the LED chip 110 can be prevented.

According to the present embodiment, the provision of the groove 106 not only prevents short circuiting of the LED chip 110, but also allows the sealing layer 138 to be uniformly filled and the cover glass 140 to be planar. Also, the display characteristics of the display device can be prevented from decreasing. The configuration of the sealing layer 138 and the cover glass 140 described in this embodiment can also be applied to the pixel structure illustrated in the first to third embodiments and the fifth embodiment.

What is claimed is:

1. An LED module, comprising:
a first electrode on an insulating surface;
a second electrode adjacent to the first electrode;
at least one groove arranged between the first electrode and the second electrode on the insulating surface; and
an LED chip disposed over the first electrode and the second electrode, wherein
the LED chip is connected to the first electrode and the second electrode through conductive members.

2. The LED module according to claim 1, wherein the at least one groove includes a plurality of grooves, and the plurality of grooves are arranged between the first electrode and the second electrode.

3. The LED module according to claim 1, wherein the at least one groove includes a plurality of grooves, and the plurality of grooves include a first groove along at least one side of the first electrode and a second groove along at least one side of the second electrode.

4. The LED module according to claim 1, wherein the at least one groove includes a plurality of grooves, and the plurality of grooves include a first groove having a U-shape or a C-shape and a second groove having a U-shape or a C-shape.

5. The LED module according to claim 1, wherein the insulating surface is formed by a surface of a first insulating layer, and the at least one groove is a region where the first insulating layer is removed.

6. The LED module according to claim 1, wherein the insulating surface has liquid-repellency in a region other than a region overlapping the first electrode and the second electrode and a region of the at least one groove.

7. The LED module according to claim 1, further comprising:
a first structure overlapping the first electrode;
a second structure overlapping the second electrode and separated from the first structure; and
a second insulating layer covering the first structure and the second structure arranged on the insulating surface,
wherein the at least one groove is located between the first structure and the second structure.

8. The LED module according to claim 1, wherein the LED chip has a first chip electrode and a second chip electrode adjacent to the first chip electrode, and
the first chip electrode is connected to the first electrode and the second chip electrode is connected to the second chip electrode through the conductive members, respectively.

9. A display device, comprising:
a first electrode arranged on an insulating surface on which a pixel is arranged;
a second electrode adjacent to the first electrode;
at least one groove arranged between the first electrode and the second electrode on the insulating surface; and
an LED chip connected to the first electrode and the second electrode, wherein
the LED chip is connected to the first electrode and the second electrode through conductive members, and
the at least one groove overlaps the LED chip.

10. The display device according to claim 9, wherein the at least one groove includes a plurality of grooves, and the plurality of grooves are arranged between the first electrode and the second electrode.

11. The display device according to claim 9, wherein the at least one groove includes a plurality of grooves, and the plurality of grooves include a first groove along at least one side of the first electrode and a second groove along at least one side of the second electrode.

12. The display device according to claim 9, wherein the at least one groove includes a plurality of grooves, and the plurality of grooves include a first groove having a U-shape or a C-shape and a second groove having a U-shape or a C-shape.

13. The display device according to claim 9, wherein the insulating surface is formed by a surface of a first insulating layer, and the at least one groove is a region where the first insulating layer is removed.

14. The display device according to claim 9, wherein the insulating surface has liquid-repellency in a region other than a region overlapping the first electrode and the second electrode and a region of the at least one groove.

15. The display device according to claim 9, further comprising:
a first structure overlapping the first electrode;
a second structure overlapping the second electrode and separated from the first structure; and
a second insulating layer covering the first structure and the second structure arranged on the insulating surface,
wherein the at least one groove is located between the first structure and the second structure.

16. The display device according to claim 9, wherein the LED chip has a first chip electrode and a second chip electrode adjacent to the first chip electrode, and
the first chip electrode is connected to the first electrode and the second chip electrode is connected to the second chip electrode through the conductive members, respectively.
